(19) United States
(12) Patent Application Publication
(10) Pub. No.: US 2026/0107532 A1
(43) Pub. Date: Apr. 16, 2026

(54) SEMICONDUCTOR DEVICE

(71) Applicant: Fujitsu Limited, Kawasaki-shi (JP)

(72) Inventors: Maciej Franciszek MATYS, Atsugi (JP); Atsushi YAMADA, Hiratsuka (JP)

(73) Assignee: Fujitsu Limited, Kawasaki-shi (JP)

(21) Appl. No.: 19/357,170

(22) Filed: Oct. 14, 2025

(30) Foreign Application Priority Data
Oct. 16, 2024 (JP) 2024-180585

(51) Int. Cl. H10D 62/815; H10D 30/47; H10D 62/824; H10D 62/85

(52) U.S. Cl. CPC H10D 62/8164; H10D 30/475; H10D 62/824; H10D 62/8503

(57) ABSTRACT

A semiconductor device includes a substrate, a first barrier layer provided on the substrate, a second barrier layer provided on the first barrier layer, and a channel layer provided on the second barrier layer. The first barrier layer has a superlattice structure including a first nitride semiconductor layer including Al, and a second nitride semiconductor layer including Ga. The second barrier layer includes a third nitride semiconductor layer including Al and Ga. The channel layer includes a fourth nitride semiconductor layer including Ga. A surface of the second barrier layer facing the channel layer has a nitrogen polarity.

### CROSS-REFERENCE TO RELATED APPLICATIONS

This application is based upon and claims the benefit of priority of the prior Japanese Patent Application No. 2024-180585, filed on October 16, 2024, the entire contents of which are incorporated herein by reference.

### FIELD

The embodiments discussed herein are related to semiconductor devices.

### BACKGROUND

As semiconductor devices using a nitride semiconductor, there are various reports on field effect transistors, particularly high electron mobility transistors (HEMTs). An example of the HEMT using a nitride semiconductor has a channel layer is provided on a barrier layer with an upper surface having a nitrogen polarity.

Examples of the related art include Japanese Laid-Open Patent Publication No. 2016-062987, U.S. Patent Application Publication US 2021/0057560 A1, U.S. Patent Application Publication US 2020/0227542 A1, and Japanese Laid-Open Patent Publication No. 2011-100772, for example.

There are increased demands to improve an output of the semiconductor device using a nitride semiconductor.

### SUMMARY

Accordingly, it is an object in one aspect of the embodiments to provide a semiconductor device capable of improving an output of the semiconductor device.

According to one aspect of the embodiments, a semiconductor device includes a substrate; a first barrier layer provided on the substrate; a second barrier layer provided on the first barrier layer; and a channel layer provided on the second barrier layer, wherein the first barrier layer has a superlattice structure including a first nitride semiconductor layer including Al, and a second nitride semiconductor layer including Ga, the second barrier layer includes a third nitride semiconductor layer including Al and Ga, the channel layer includes a fourth nitride semiconductor layer including Ga, and a surface of the second barrier layer facing the channel layer has a nitrogen polarity.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross sectional view illustrating a semiconductor device according to a first embodiment;

FIG. 2 is a cross sectional view illustrating a first barrier layer;

FIG. 3 is a cross sectional view illustrating a semiconductor device according to a reference example;

FIG. 4 is a diagram illustrating lower ends of conduction bands of the semiconductor devices;

FIG. 5 is a diagram illustrating electron concentrations;

FIG. 6 is a cross sectional view illustrating a sample used for measurement of a sheet resistance;

FIG. 7 is a diagram illustrating a measurement result of the sheet resistance;

FIG. 8 is a diagram illustrating an unevenness of a surface of the sample;

FIG. 9 is a diagram illustrating a discrete package according to a second embodiment;

FIG. 10 is a circuit diagram illustrating a power factor correction circuit according to a third embodiment;

FIG. 11 is a circuit diagram illustrating a power supply according to a fourth embodiment; and

FIG. 12 is a circuit diagram illustrating an amplifier according to a fifth embodiment.

### DESCRIPTION OF EMBODIMENTS

Hereinafter, embodiments of the present disclosure will be specifically described with reference to the accompanying drawings. In the present specification and the drawings, constituent elements or components having substantially the same functional configuration are designated by the same reference numerals, and a redundant description thereof may be omitted.

### First Embodiment

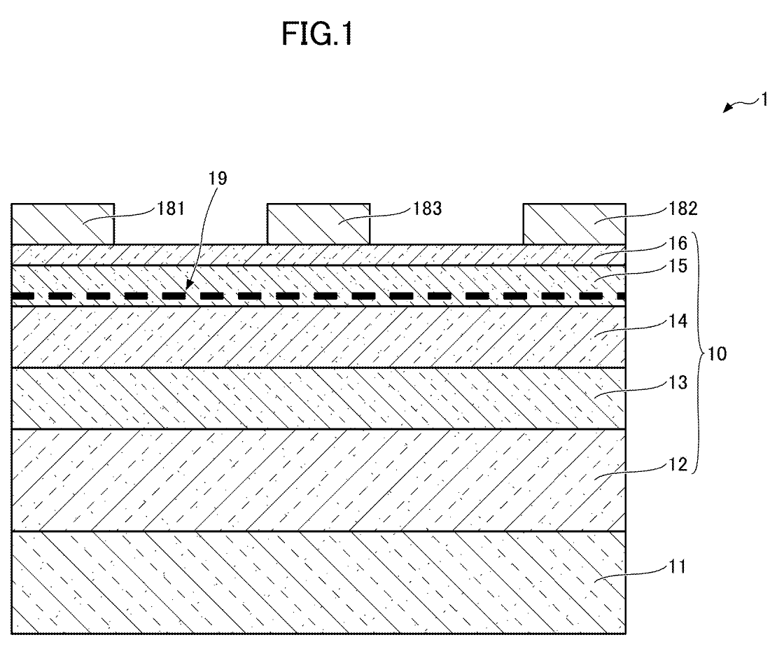

A first embodiment will be described. A first embodiment relates to a semiconductor device including a high electron mobility transistor (HEMT). FIG. 1 is a cross sectional view illustrating the semiconductor device according to the first embodiment.

As illustrated in FIG. 1, a semiconductor device 1 according to the first embodiment includes a substrate 11, and a nitride semiconductor multilayer structure 10 provided above the substrate 11. The nitride semiconductor multilayer structure 10 includes a buffer layer 12, a first barrier layer 13, a second barrier layer 14, a channel layer 15, and a cap layer 16. The buffer layer 12 is provided on the substrate 11. The first barrier layer 13 is provided on the buffer layer 12. The second barrier layer 14 is provided on the first barrier layer 13. The channel layer 15 is provided on the second barrier layer 14. The cap layer 16 is provided on the channel layer 15.

The substrate 11 is a SiC substrate, a GaN substrate, or a sapphire substrate, for example. In a case where the substrate 11 is the SiC substrate, an upper surface of the substrate 11 has a carbon (C) polarity. In a case where the substrate 11 is the GaN substrate, the upper surface of the substrate 11 has a nitrogen (N) polarity. In a case where the substrate 11 is the sapphire substrate, the upper surface of the substrate 11 has an off angle. A magnitude of the off angle is approximately 4°, for example. The buffer layer 12 includes a AlN layer, a GaN layer, a AlGaN layer, or an arbitrary combination thereof. A Al composition of the AlGaN layer may be constant or may vary. For example, in a case where the buffer layer 12 includes a GaN layer and a AlGaN layer provided on the GaN layer, the Al composition of the AlGaN layer may increase as a distance from the GaN layer increases. A thickness of the buffer layer 12 is approximately 1 μm, for example.

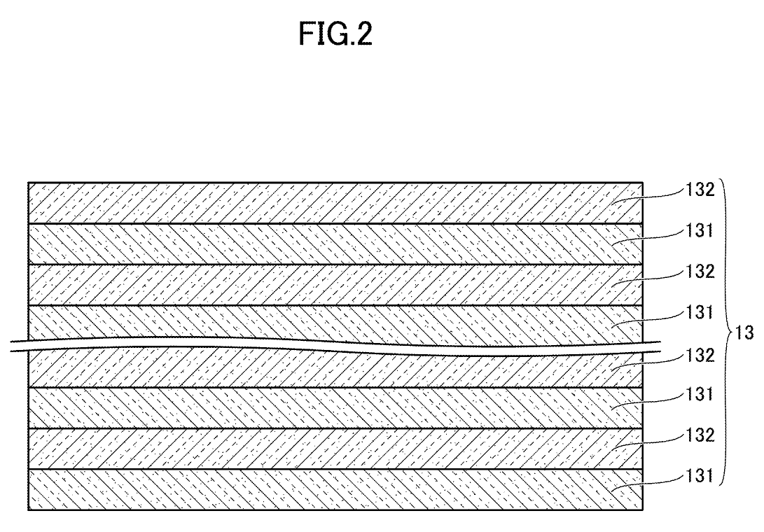

FIG. 2 is a cross sectional view illustrating the first barrier layer 13. The first barrier layer 13 has a superlattice structure including a first nitride semiconductor layer 131 including Al, and a second nitride semiconductor layer 132 including Ga. That is, as illustrated in FIG. 2, the first barrier layer 13 includes one or more pairs of the first nitride semiconductor layer 131 and the second nitride semiconductor layer 132. In a case where the first barrier layer 13 includes two or more pairs of the first nitride semiconductor layer 131 and the second nitride semiconductor layer 132, the first nitride semiconductor layer 131 and the second nitride semiconductor layer 132 are alternately arranged. The first nitride semiconductor layer 131 is a AlN layer having a thickness in a range greater than or equal to 1 nm and less than or equal to 10 nm, for example. The second nitride semiconductor layer 132 is a GaN layer having a thickness in a range greater than or equal to 1 nm and less than or equal to 30 nm, for example. The thickness of the second nitride semiconductor layer 132 may be equal to the thickness of the first nitride semiconductor layer 131, or may be greater than the thickness of the first nitride semiconductor layer 131, or may be less than the thickness of the first nitride semiconductor layer 131.

The second barrier layer 14 includes a third nitride semiconductor layer including Al and Ga. The third nitride semiconductor layer is a AlₓGa₁₋ₓN layer having a thickness in a range greater than or equal to 5 nm and less than or equal to 40 nm, for example. A value of x is in a range greater than or equal to 0.10 and less than or equal to 0.50, for example. The channel layer 15 includes a fourth nitride semiconductor layer including Ga. The fourth nitride semiconductor layer is a GaN layer having a thickness in a range greater than or equal to 10 nm and less than or equal to 30 nm, for example. The cap layer 16 includes a AlN layer, a GaN layer, a AlGaN layer, or an arbitrary combination thereof. A thickness of the cap layer 16 is in a range greater than or equal to 1 nm and less than or equal to 5 nm, for example. A two dimensional electron gas (2DEG) 19 is present near a lower surface of the channel layer 15.

The semiconductor device 1 includes a source electrode 181, a drain electrode 182, and a gate electrode 183. The source electrode 181, the drain electrode 182, and the gate electrode 183 are provided on the nitride semiconductor multilayer structure 10. The gate electrode 183 is provided between the source electrode 181 and the drain electrode 182. The source electrode 181 and the drain electrode 182 are in contact with the nitride semiconductor multilayer structure 10. The gate electrode 183 may be in contact with the nitride semiconductor multilayer structure 10, or a gate insulating film may be provided between the gate electrode 183 and the nitride semiconductor multilayer structure 10.

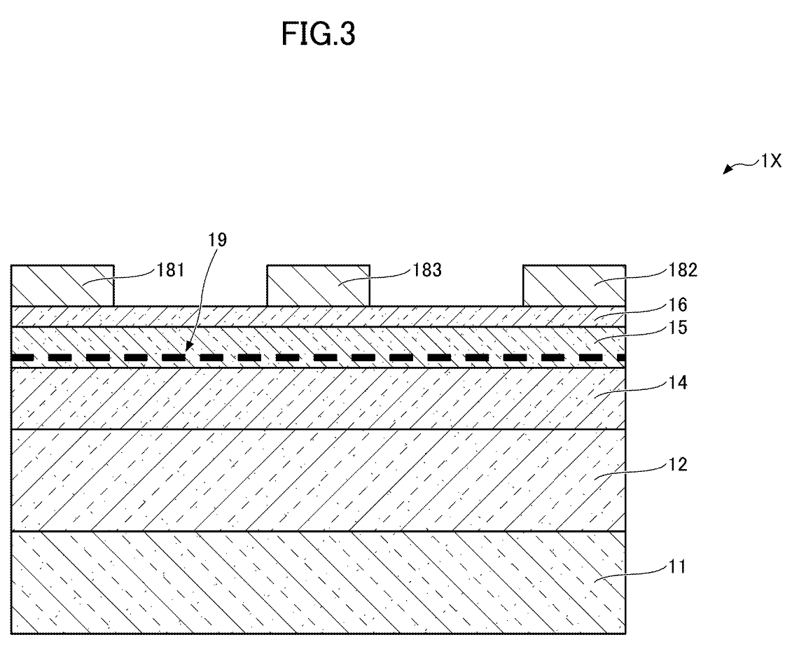

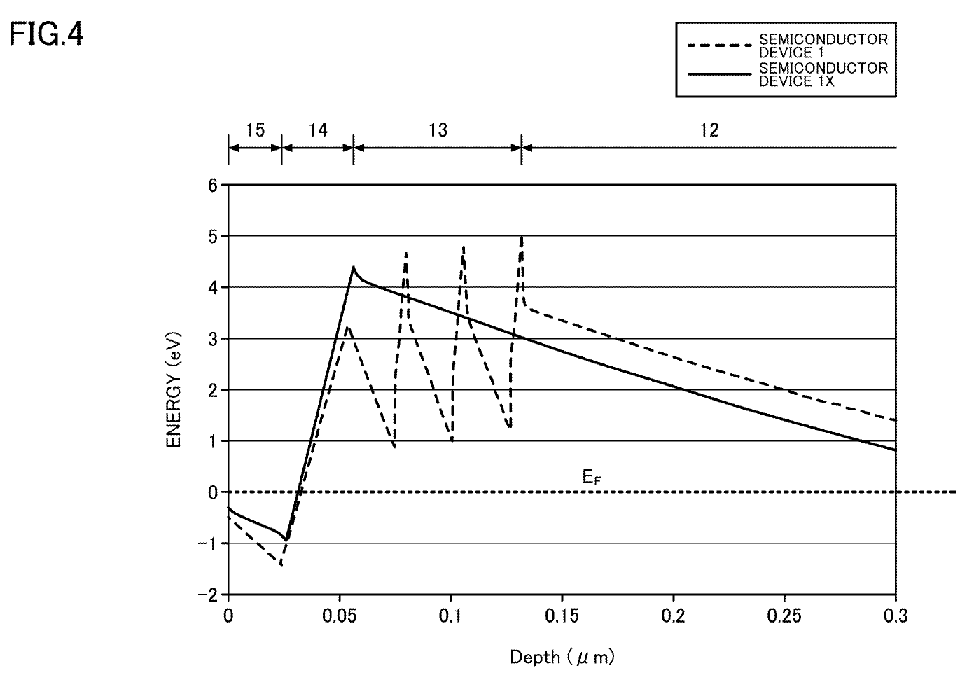

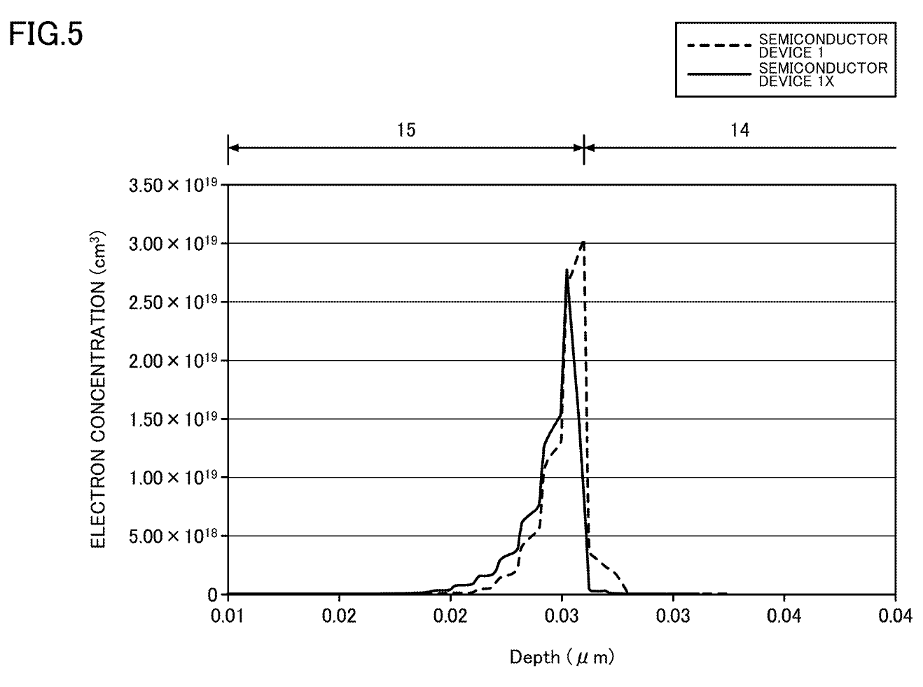

Next, a band structure and an electron concentration in the semiconductor device 1 will be described in comparison with those of a reference example. It is assumed that the number of pairs of the first nitride semiconductor layer 131 and the second nitride semiconductor layer 132 is three, the first nitride semiconductor layer 131 is a AlN layer having a thickness of 5 nm, the second nitride semiconductor layer 132 is a GaN layer having a thickness of 20 nm, and the buffer layer 12 is a GaN layer. As illustrated in FIG. 3, in a semiconductor device 1X according to the reference example, the first barrier layer 13 is not provided, and the buffer layer 12 is in contact with the second barrier layer 14. FIG. 3 is a cross sectional view illustrating the semiconductor device according to the reference example. FIG. 4 is a diagram illustrating lower ends of the conduction bands of the semiconductor devices. FIG. 5 is a diagram illustrating the electron concentrations. In FIG. 4, the abscissa indicates a depth from an upper surface of the channel layer 15, and the ordinate indicates an energy at the lower end of the conduction band. An energy at a Fermi level EF is 0 eV. In FIG. 5, the abscissa indicates the depth from the upper surface of the channel layer 15, and the ordinate indicates the electron concentration.

As illustrated in FIG. 4, in the case of the semiconductor device 1 according to this embodiment, an energy of the channel layer 15 exhibits a sharp transition and the energy near a lower surface of the channel layer 15 is low when compared to those of the semiconductor device 1X according to the reference example. Accordingly, as illustrated in FIG. 5, a confinement effect of the 2DEG 19 in the semiconductor device 1 is high and a maximum value of the electron concentration is high compared to those of the semiconductor device 1X according to the reference example. For this reason, according to the semiconductor device 1, it is possible to improve an output of the semiconductor device 1. In addition, a short-channel effect of the semiconductor device 1 can be suppressed.

A density of the 2DEG 19 increases as the number of pairs of the first nitride semiconductor 131 and the second nitride semiconductor 132 increases. On the other hand, if the number of pairs of the first nitride semiconductor 131 and the second nitride semiconductor 132 is six or more, an electric field may vary, and a mobility of electrons in the 2DEG 19 may decrease. For this reason, the number of pairs of the first nitride semiconductor layer 131 and the second nitride semiconductor layer 132 is preferably five or less.

The nitride semiconductor multilayer structure 10 can be formed by metal organic chemical vapor deposition (MOCVD), for example. The source electrode 181, the drain electrode 182, and the gate electrode 183 may be formed by vapor deposition and lift-off, for example.

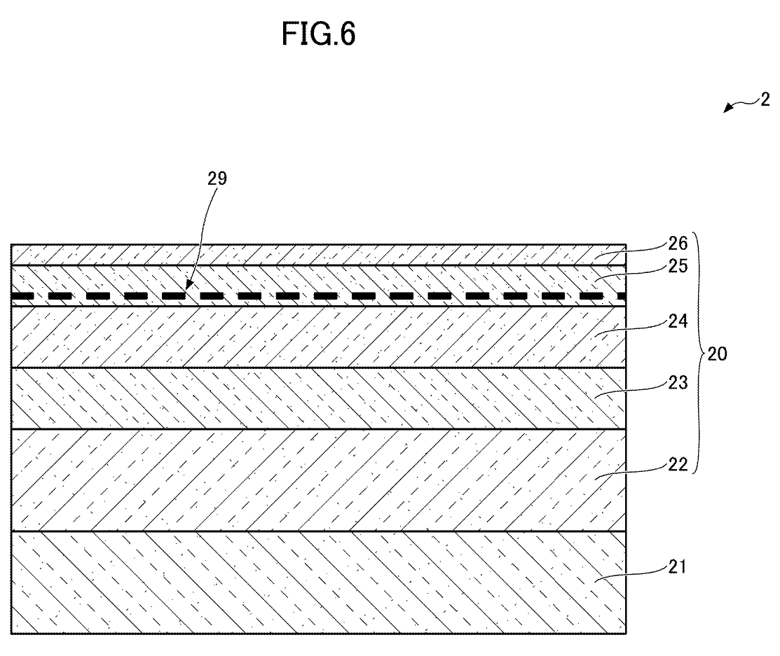

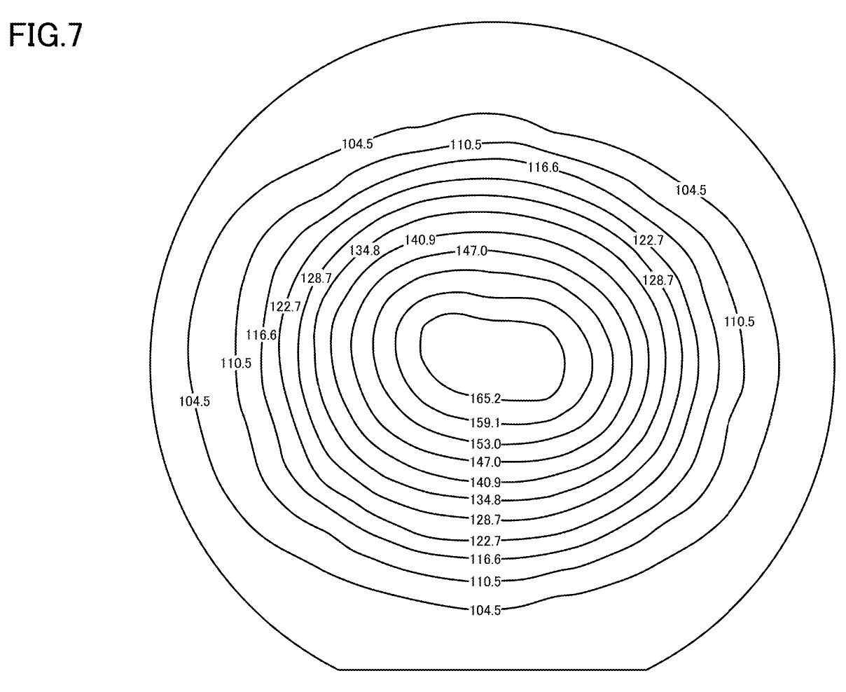

Next, a measurement result of a sheet resistances of a sample of the nitride semiconductor multilayer structure formed by the present inventors will be described. FIG. 6 is a cross sectional view illustrating a sample used for measurement of the sheet resistance. FIG. 7 is a diagram illustrating the measurement result of the sheet resistance. Numerical values in FIG. 7 indicate sheet resistances (Ω/sq.).

A sample 2 used for the measurement of the sheet resistance includes a substrate 21, and a nitride semiconductor multilayer structure 20 provided above the substrate 21. The nitride semiconductor multilayer structure 20 includes a buffer layer 22, a first barrier layer 23, a second barrier layer 24, a channel layer 25, and a cap layer 26. The buffer layer 22 is provided on the substrate 21. The first barrier layer 23 is provided on the buffer layer 22. The second barrier layer 24 is provided on the first barrier layer 23. The channel layer 25 is provided on the second barrier layer 24. The cap layer 26 is provided on the channel layer 25.

The substrate 21 is a sapphire substrate with a diameter of 7.62 cm (3 inches) and an off angle of 4°. The buffer layer 22 includes a AlN layer having a thickness of 100 nm, and a GaN layer having a thickness of 1 μm. The AlN layer is provided on the substrate 21, and the GaN layer is provided on the AlN layer. The first barrier layer 23 includes Al layers and GaN layers that are alternately arranged, so that pairs of the Al layer and the GaN layer are stacked. The AlN layers have a thickness of 10 nm, and the GaN layers have a thickness of 5 nm. The first barrier layer 23 includes four pairs of AlN layer and the GaN layer. The second barrier layer 24 is a AlGaN layer having a thickness of 30 nm. The channel layer 25 is a GaN layer having a thickness of 20 nm. The cap layer 26 includes a AlGaN layer having a thickness of 3 nm, and a GaN layer having a thickness of 2 nm. The AlGaN layer is provided on the channel layer 25, and the GaN layer is provided on the AlGaN layer. The 2DEG 29 is present in the vicinity of the lower surface of the channel layer 25.

As illustrated in FIG. 7, the sheet resistance was approximately 170 Ω/sq. at a maximum, and an average value of the sheet resistance was 131.0 Ω/sq. Compared to the sheet resistance (approximately 300.0 Ω/sq.) in the case of the semiconductor device 1X according to the reference example that is not provided with the first barrier layer 23, a significantly low sheet resistance was obtained in the case of the semiconductor device 1 according to this embodiment.

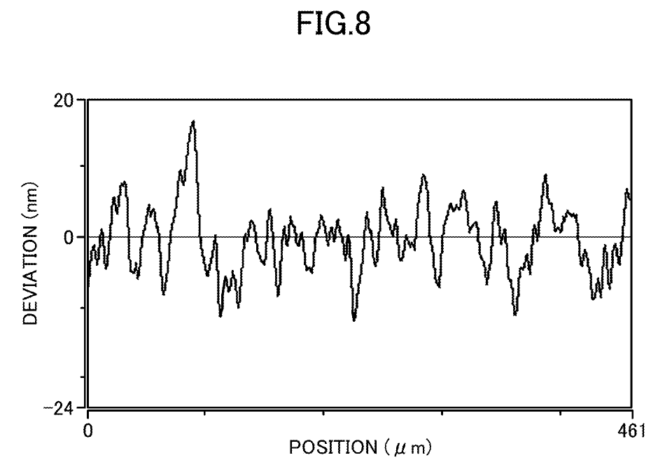

In the sample 2, a surface of the cap layer 26 had a good flatness. FIG. 8 is a diagram illustrating an unevenness of a surface of the sample. In FIG. 8, the abscissa indicates a position on a plane parallel to the surface of the cap layer 26, and the ordinate indicates a deviation (or displacement) from a reference plane parallel to the surface of the cap layer 26. As illustrated in FIG. 8, an absolute value of the deviation was small, and a good flatness was obtained for the surface of the cap layer 26.

### Second Embodiment

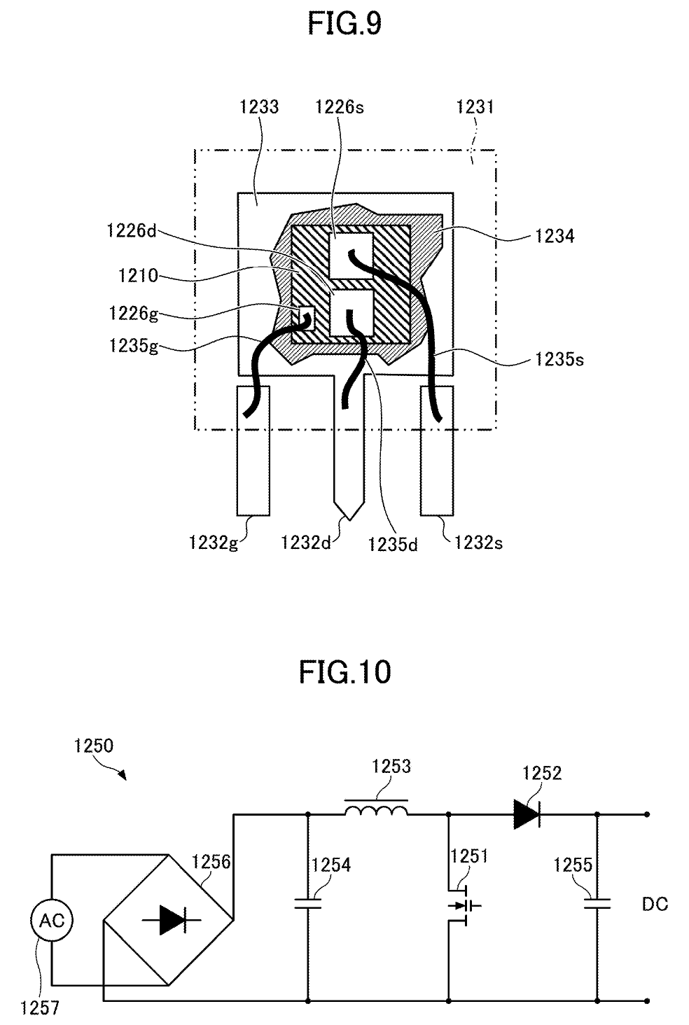

Next, a second embodiment will be described. The second embodiment relates to a discrete package of a HEMT. FIG. 9 is a diagram illustrating a discrete package according to the second embodiment.

In the second embodiment, as illustrated in FIG. 9, a back surface of a semiconductor device 1210 having the same configuration as that of the first embodiment is fixed to a land (die pad) 1233 using a die attach material 1234, such as solder or the like. In addition, one end of a wire 1235d, such as a Al wire or the like, is connected to a drain pad 1226d that is connected to the drain electrode 182, and the other end of the wire 1235d is connected to a drain lead 1232d integrated with the land 1233. One end of a wire 1235s, such as a Al wire or the like, is connected to a source pad 1226s that is connected to the source electrode 181, and the other end of the wire 1235s is connected to a source lead 1232s that is independent of the land 1233. One end of a wire 1235g, such as a Al wire or the like, is connected to a gate pads 1226g that is connected to the gate electrode 183, and the other end of the wires 1235g is connected to a gate lead 1232g that is independent of the land 1233. The land 1233, the semiconductor device 1210, or the like are packaged by a mold resin 1231, so that a portion of the gate lead 1232g, a portion of the drain lead 1232d, and a portion of the source lead 1232s protrude from the mold resin 1231.

Such a discrete package described above can be manufactured in the following manner, for example. First, the semiconductor device 1210 is fixed to the land 1233 of a lead frame, using the die attach material 1234, such as the solder or the like. Next, by bonding using the wires 1235g, 1235d, and 1235s, the gate pad 1226g is connected to the gate lead 1232g of the lead frame, the drain pad 1226d is connected to the drain lead 1232d of the lead frame, and the source pad 1226s is connected to the source lead 1232s of the lead frame. Thereafter, encapsulation using the mold resin 1231 is performed by transfer molding. Subsequently, the lead frame is removed.

### Third Embodiment

Next, a third embodiment will be described. The third embodiment relates to a power factor correction (PFC) circuit including a HEMT. FIG. 10 is a circuit diagram illustrating the PFC circuit according to the third embodiment.

A PFC circuit 1250 includes a switching element (transistor) 1251, a diode 1252, a choke coil 1253, capacitors 1254 and 1255, a diode bridge 1256, and an alternating current (AC) power supply 1257. A drain electrode of the switching element 1251, an anode terminal of the diode 1252, and one terminal of the choke coil 1253 are connected. A source electrode of the switching element 1251, one terminal of the capacitor 1254, and one terminal of the capacitor 1255 are connected. The other terminal of the capacitor 1254 and the other terminal of the choke coil 1253 are connected. The other terminal of the capacitor 1255 and a cathode terminal of the diode 1252 are connected. In addition, a gate driver is connected to a gate electrode of the switching element 1251. The AC power supply 1257 is connected between both terminals of the capacitor 1254 via the diode bridge 1256. A DC power supply is connected between both terminals of the capacitor 1255. In this embodiment, a semiconductor device having the same configuration as that of the first embodiment is used for the switching element 1251.

When manufacturing the PFC circuit 1250, the switching element 1251 is connected to the diode 1252, the choke coil 1253, or the like using solder or the like, for example.

### Fourth Embodiment

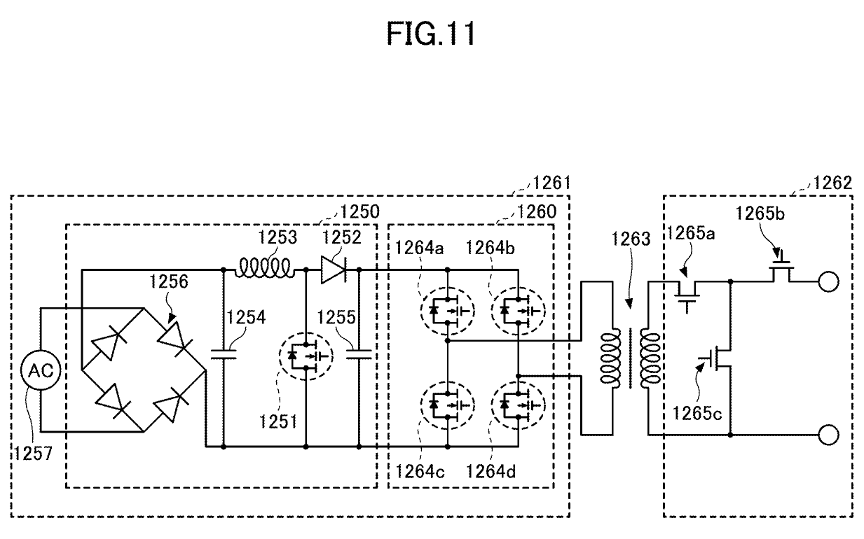

Next, a fourth embodiment will be described. The fourth embodiment relates to a power supply including a HEMT, which is suitable for use as a server power supply. FIG. 11 is a circuit diagram illustrating the power supply according to the fourth embodiment.

The power supply includes a high-voltage primary circuit 1261, a low-voltage secondary circuit 1262, and a transformer 1263 disposed between the primary circuit 1261 and the secondary circuit 1262.

The primary circuit 1261 includes the PFC circuit 1250 according to the third embodiment, and an inverter circuit, such as a full-bridge inverter circuit 1260, for example, that is connected between both terminals of the capacitor 1255 of the PFC circuit 1250. The full-bridge invertor circuit 1260 includes a plurality of (four in this example) switching elements 1264a, 1264b, 1264c and 1264d.

The secondary circuit 1262 includes a plurality of (three in this example) switching elements 1265a, 1265b, and 1265c.

In this embodiment, the switching element 1251 of the PFC circuit 1250 and the switching elements 1264a, 1264b, 1264c, and 1264d of the full-bridge invertor circuit 1260, which constitute the primary circuit 1261, have the same configuration as that of the first embodiment. On the other hand, a general metal-insulator-semiconductor field effect transistor (MISFET) is used for the switching elements 1265a, 1265b, and 1265c of the secondary circuit 1262.

### Fifth Embodiment

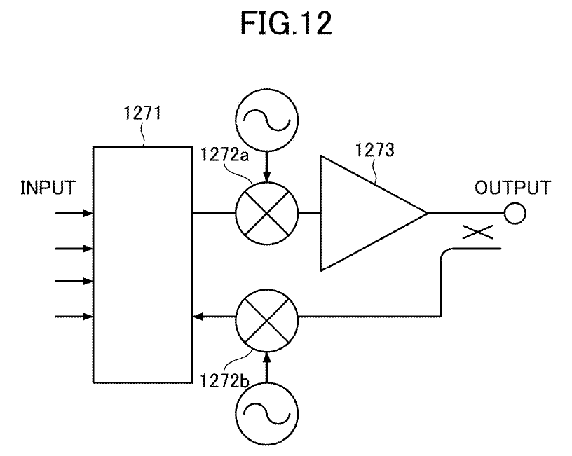

Next, a fifth embodiment will be described. The fifth embodiment relates to an amplifier including a HEMT. FIG. 12 is a circuit diagram illustrating the amplifier according to the fifth embodiment.

As illustrated in FIG. 12, the amplifier includes a digital predistortion circuit 1271, mixers 1272a and 1272b, and a power amplifier 1273.

The digital predistortion circuit 1271 compensates for nonlinear distortions of an input signal. The mixer 1272a mixes the input signal compensated of the nonlinear distortions and a AC signal. The power amplifier 1273 includes a semiconductor device having the same configuration as that of the first embodiment, and amplifies the input signal mixed with the AC signal. In this embodiment, by switching a switch, for example, an output-side signal can be mixed with the AC signal in the mixer 1272b and sent to the digital predistortion circuit 1271. The amplifier can be used as a high-frequency amplifier or a high-power amplifier. The high-frequency amplifier can be used in a transmission and reception device for a mobile phone base station, a radar device, and a microwave generation device.

A silicon substrate, a AlN substrate, or a diamond substrate may be used for the substrate of the semiconductor device. The substrate may be conductive, semi-insulating or insulating.

According to the embodiments of the present disclosure, it is possible to improve the output of the semiconductor device using a nitride semiconductor.

Although the embodiments are numbered with, for example, “first,” “second,” “third,” “fourth,” or “fifth,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a substrate;
a first barrier layer provided on the substrate;
a second barrier layer provided on the first barrier layer; and
a channel layer provided on the second barrier layer, wherein:
the first barrier layer has a superlattice structure including a first nitride semiconductor layer including Al, and a second nitride semiconductor layer including Ga,
the second barrier layer includes a third nitride semiconductor layer including Al and Ga,
the channel layer includes a fourth nitride semiconductor layer including Ga, and
a surface of the second barrier layer facing the channel layer has a nitrogen polarity.

2. The semiconductor device as claimed in claim 1, wherein:
the first nitride semiconductor layer is a AlN layer, and
the second nitride semiconductor layer is a GaN layer.

3. The semiconductor device as claimed in claim 1, wherein:
the third nitride semiconductor layer is a AlGaN layer, and
the fourth nitride semiconductor layer is a GaN layer.

4. The semiconductor device as claimed in claim 1, further comprising:
a source electrode, a gate electrode, and a drain electrode provided on the channel layer, respectively.

5. The semiconductor device as claimed in claim 1, wherein the substrate is a SiC substrate, a GaN substrate, or a sapphire substrate.

6. The semiconductor device as claimed in claim 1, further comprising:
a buffer layer provided between the substrate and the first barrier layer.

7. The semiconductor device as claimed in claim 1, further comprising:
a cap layer provided on the channel layer.

8. An amplifier comprising:
the semiconductor device according to claim 1.

9. A power supply comprising:
the semiconductor device according to claim 1.
